(19) United States
(12) Patent Application Publication
(10) Pub. No.: US 2017/0131332 A1
(43) Pub. Date: May 11, 2017

(54) SENSOR DEVICE COMMUNICATIONS APPARATUS AND METHOD

(71) Applicant: Embertec Pty Ltd, Dulwich (AU)

(72) Inventor: Domenico Gelonese, Dulwich (AU)

(21) Appl. No.: 15/335,540

(22) Filed: Oct. 27, 2016

(30) Foreign Application Priority Data
Nov. 9, 2015 (AU) 2015904599

(51) Int. Cl. G01R 22/06; G01R 22/10; H04W 4/00

(52) U.S. Cl. CPC G01R 22/063; H04W 4/008; G01R 22/10; H04W 84/18

(57) ABSTRACT

A sensor device receives energy usage data from a standby power controller, and transmits the energy usage data to a remote monitoring entity (e.g., a utility) via a communications device. The energy usage data may include appliance energy usage data representing energy drawn through the standby power controller, and/or household energy usage data representing energy usage measured by an electricity meter. The energy usage data is transmitted to the communications device via wireless communications such as Bluetooth or Wi-Fi, whereas the communications device transmits the energy usage data to the remote monitoring entity via the internet. Household energy usage is transmitted from the electricity meter to the sensor device via a low-data, high-latency protocol such as ZigBee.

### FIELD OF THE INVENTION

This invention relates to a facility for communicating electric energy usage, including communicating usage with a standby power controller having a data communication capability.

### BACKGROUND OF THE INVENTION

The following references to and descriptions of prior proposals or products are not intended to be, and are not to be construed as, statements or admissions of common general knowledge in the art. In particular, the following discussion does not necessarily relate to what is commonly or well known by the person skilled in the art. This discussion is merely provided to grant the reader a better appreciation for the invention.

Electrical energy use by individual homes, offices, or other household, commercial, or industrial premises, has traditionally been measured by on-site accumulation meters. Such meters continuously measure the instantaneous power being supplied to the premises, and use these measurements over time to determine the energy supplied to the premises over a time period.

Accumulation meters are read periodically, and the charge for energy to the premises for the period is calculated. The meter reading often requires that a meter reader visit the premises, typically on a monthly or quarterly basis. The meter reader's visit is a significant cost to the utility supplying electricity to the premises.

No information about patterns of energy usage is available from the accumulation meter. The only information is the total energy used in the period since the last reading. Information concerning the time of day, day of week, and time of year of energy usage is becoming increasingly desirable.

The price which an energy retailer pays electricity generators for electricity is affected by many factors, including supply contracts and government regulation, but in general is driven by supply and demand. That is, in times of high demand, the price paid by the electricity retailer increases. Demand varies continuously by time of day and time of year. The price variation may be many orders of magnitude, with (for example) the marginal price of an additional kWh (kilowatt hour) varying from one cent to more than ten thousand dollars.

Due to commercial realities, political constraints, and technical limitations, it is not possible for the energy retailer to simply pass on the marginal cost directly to the consumer. The cost to the consumer of a kWh is generally fixed at a price significantly greater than the lowest marginal cost payable by the energy retailer, but very much less than the maximum possible marginal cost payable by the energy retailer, generally from tens to hundreds of cents per kWh. However, the energy retailer in many cases is seeking to move demand away from peak periods by implementing consumer tariffs which vary by time of day and time of year, with higher prices for periods which are expected to be peak demand periods.

In order to implement such tariffs, interval meters have been introduced. Interval meters provide coarse-grained time of use data, usually recording the energy use over half-hour intervals, or occasionally quarter-hour intervals. Even more finely-grained information is being sought by energy utilities and others. Interval meters may also be so-called Smartmeters, with the ability to communicate usage data to a utility without the need for a meter reader to visit the premises. This communication may be over communication channels with unpredictable or high latency and with low data rates, such as mesh networks or power line communication networks.

There is currently world-wide concern about the level of use of electrical energy for both domestic and commercial uses. In part this concern is based on the greenhouse gas production associated with the generation of electrical energy, and the contribution of that greenhouse gas to anthropogenic global warming. There is also a concern for the capital cost involved in building the electricity generating plants and electricity distribution networks required to generate and distribute an increasing amount of electricity.

A significant contributor to the energy use of households is the so-called “plug loads”. These are the devices which are powered by plugging on to a general power outlet (GPO), which may also be simply called a “wall socket.” These plug loads include audiovisual equipment including devices such as televisions, television decoders, television recorders, and sound equipment now found in virtually all homes. Plug loads also include semi-fixed small appliances and lamps. Plug loads are typically not moved around within a house. Their usage is often highly discretionary, and highly dependent upon individual households' lifestyle choices.

Efforts have been made to reduce or control the use of energy by television receivers and associated audiovisual equipment, in particular with the use of standby power controllers, and these have met with considerable success.

Information concerning the usage patterns and energy usage of plug loads is difficult to obtain, but has become very important to energy supply and distribution utilities, as well as to householders.

### SUMMARY OF THE INVENTION

An exemplary version of the invention involves a sensor adapted to control a standby power controller, including:

a power sensor adapted to measure power drawn through the standby power controller and to output the result of the measurement as appliance energy usage data;

a processor adapted to determine from the appliance energy usage data that devices connected to the standby power controller are in a low power standby power state;

means to determine that a television connected to the standby power controller is in an active standby mode;

a switch adapted to operate to remove power from the television when the active standby or low power standby state is determined; and

a first transceiver adapted to communicate the appliance energy usage data to a communications device, the communications device being adapted to transmit the appliance energy usage data to a remote monitoring entity.

Preferably, the sensor further includes a second transceiver adapted to receive household energy usage data from an electricity meter;

the second transceiver being further adapted to transmit the household energy usage data to the communications device;

the communications device communicating the household energy usage data to the remote monitoring entity.

Preferably, the communication device is intermittently available, and is one or more of a smartphone, a tablet computer and a notebook computer.

The electricity meter is preferably a Smartmeter.

The first transceiver preferably employs the Bluetooth protocol, and the second transceiver preferably employs the ZigBee protocol.

In an alternative version of the invention, the sensor device and the standby power controller are integrated within a single housing.

In an alternative version of the invention, the first transceiver is a Wi-Fi transceiver.

The invention can also or alternatively involve a sensor device including a meter data transceiver adapted to receive household energy usage data from an electricity meter,

an electronic memory adapted to store the household energy usage data;

the sensor device including a local communications transceiver adapted to transmit the household energy usage data to a communications device;

the communications device communicating the household energy usage data to a remote monitoring entity.

The invention can also or alternatively involve a method for communicating energy usage data to a remote monitoring entity, the method including providing a sensor device having a meter data transceiver which receives household energy usage data from an electricity meter, the sensor device communicating the household energy usage data to a communications device, with the communications device communicating the household energy usage data to the remote monitoring entity.

The invention can also or alternatively involve a method for communicating energy usage data to a remote monitoring entity, the method including providing a sensor device which controls a standby power controller, with the standby power controller including a power sensor which senses appliance energy usage data being energy used by one or more appliances which are supplied with power via the standby power controller, and with the sensor device communicating the appliance energy usage data to a communications device which communicates the appliance energy usage data to the remote monitoring entity.

The invention can also or alternatively involve a sensor including a first transceiver adapted to receive household energy usage data from an electricity meter;

an electronic memory adapted to store the household energy usage data;

a second transceiver adapted to transmit the household energy usage data to a communications device;

the communications device communicating the household energy usage data to a remote monitoring entity.

The sensor is adapted to control a standby power controller including a power sensor adapted to measure power drawn through the standby power controller and to output the result of the measurement as appliance energy usage data.

A processor is adapted to determine from the appliance energy usage data that devices connected to the standby power controller are in a low power standby power state

Means are provided to determine that a television connected to the standby power controller is in an active standby mode. Also provided is a switch adapted to operate to remove power from the television when the active standby or low power standby state is determined.

The second transceiver is further adapted to communicate the appliance energy usage data to the communications device for transmission to the remote monitoring entity.

### BRIEF DESCRIPTION OF THE DRAWINGS

Exemplary versions of the invention are described below in connection with the accompanying drawings wherein:

FIG. 1 is a representation of a sensor device of a standby power controller (SPC) incorporating the invention.

FIG. 2 is a representation of a further embodiment of the invention, including a Smartmeter.

FIG. 3 is a representation of a further embodiment of the invention, including a data router.

FIG. 4 is a representation of a sensor device incorporating the invention.

### DETAILED DESCRIPTION OF THE DRAWINGS

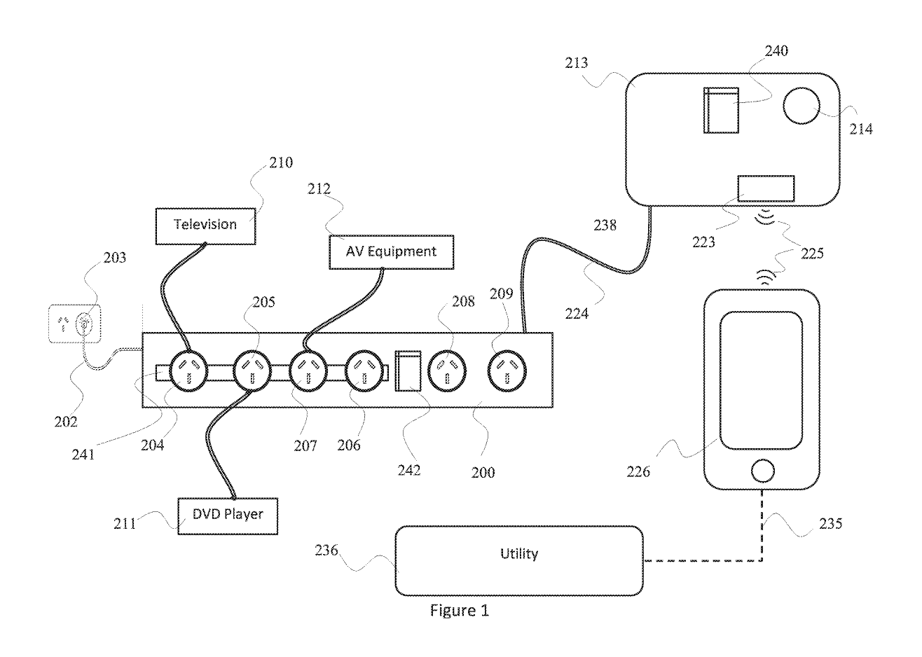

FIG. 1 depicts an exemplary version of the invention having a sensor device which controls a standby power controller (SPC) 200. An SPC is a device which controls the flow of electrical power to one or more connected appliances such that when one or more, or a particular one, of the connected appliances is in a “standby” state where it is not being used, the electrical power supply to one, all or selected ones of the connected appliances is interrupted. The depiction of FIG. 1 is illustrative only, and is not intended to limit the number or configuration of continually powered or switched or monitored main outlets on the SPC, or of communication interfaces or other functional modules.

A sensor device 213 includes a first transceiver 223 which provides a data link 225 to a communications device 226. The communications device 226 illustrated is a Smartphone. The communications device 226 provides functionality to receive data and to retransmit that data. In other versions of the invention, this functionality may be provided by a tablet computer, by another mobile communication device, or any other suitable device.

The sensor device 213 is preferably in data communication with the standby power controller (SPC) 200 via cable 224, which may also provide power to the sensor device 213. The sensor device 213 includes a short range communication means, in the illustrated embodiment a first transceiver 223, preferably a Bluetooth transceiver, though any suitable wireless technology may be employed. The cable 224 may be a fixed connection or may be plug connected at one or both ends. In an alternative version of the invention, the sensor device 213 may be integrated with the SPC body 200. In further versions of the invention, the communication means may be provided by any convenient wireless protocol, including without limitation, Bluetooth, ZigBee and RF4CE.

The standby power controller (SPC) 200 receives electrical power from a General Purpose Outlet 203 via power cord 202. The SPC 200 includes Monitored and Controlled Outlets 204, 205, 206, 207. The SPC 200 also includes Uncontrolled Outlets 208, 209. In general, any number of Monitored and Controlled Outlets and Uncontrolled Outlets may be provided. In an embodiment, the Uncontrolled Outlet(s) may be absent.

Monitored and Controlled Outlet 204 supplies electrical power to a television 210. Further Monitored and Controlled Outlets 205, 207 may provide electrical power to other audiovisual equipment, for example a DVD player 211 and audiovisual equipment 212. Regardless of whether one or more Monitored and Controlled Outlets are provided, multiple devices may be powered from one Monitored and Controlled Outlet using a powerstrip.

Modern television sets and other audiovisual equipment, when turned “off” by a remote control, enter a low power “standby” state in which energy is still consumed, although at a significantly lower level that when the audiovisual equipment is nominally “on”. When the audiovisual equipment is in this standby state it is not in use, and the power supply to it may be cut to save energy.

It is also the case that television sets may be left on for extended periods when no user is viewing the screen. This may happen when a user falls asleep in front of the television, or when a user, particularly a child or a teenager, simply leaves the vicinity of the television without turning the television off. This state may be termed “active standby.” In this state the television is not in use, and the power supply to it may be cut to save energy.

The standby power controller (SPC) 200 may detect that the television 210 has entered a standby state by any convenient means or combination of means. In order to save energy, the standby power controller (SPC) 200 operates to remove the power supply from Monitored and Controlled Outlet 204, and hence from the attached television 210, whenever the television 210 is detected to not be in use. At the same time, the SPC 200 removes power from none, some, or all of the Monitored and Controlled Outlets 205, 207, 206.

The standby power controller (SPC) 200 may include means to detect that a user is interacting with the audiovisual (AV) equipment 212 and/or the television 210. The sensor device 213 includes a remote control signal detector, depicted in FIG. 1 as an infra-red sensor 214. This sensor 214 receives IR signals from a remote control associated with the television 210 or other connected AV equipment.

It is likely that a user, when actively watching television 210, will periodically use the remote control to change channels, adjust volume, mute commercials, etc. Thus a remote control signal detector, such as IR sensor 214, can be used as a usage sensor. If no remote control activity is detected by the IR sensor 214 for a period of time, the assumption may be made that the television is not in use, and the power supply to the Monitored and Controlled Outlet 204, and hence to the television 210, is interrupted. This may be achieved by using a countdown timer which starts from a specific initial value equal to a particular time period, say one hour, and having this countdown time continuously decrement. Each detected use of the remote control will reset the countdown timer to the initial value. When the countdown time reaches zero, there has been no remote control activity for the time period, the television 210 is assumed to not be in active use, and the electricity supply to the Monitored and Controlled Outlet 204, and hence to the television 210, is interrupted.

It may be sufficient to determine that a user is present in the vicinity of the television 210 in order to decide that the television 210 should not be turned off. Any suitable sensor may be used for determining that a user is present, and thus that power to the television should not be interrupted. These include, without limitation, passive IR sensors, ultrasonic sensors, cameras, any other passive or active movement sensors, and sound detectors.

Whatever means is used to determine that the television 210 is on, but not in use, it is unlikely to be completely free of false positives, that is, determining that the television 210 is in active standby and not in use when the television 210 is in fact in use. If the television 210 is turned off when a user is still watching a program, the user will be irritated. Repeated occurrences are likely to lead to the power control function of the standby power controller (SPC) 200 being bypassed, preventing power savings.

A warning LED can also be provided such that when the standby power controller (SPC) 200 determines that the television 210 is in active standby, the warning LED will flash to alert any user to the imminent shutdown of the power to the television 210. In the case where there is a false positive, that is, there is a user watching the television, the user may react to observing the flashing of the warning LED by pressing a key on the remote control. The IR signal from the remote control is detected by the IR sensor 214, and the countdown timer is reset, preventing interruption of power to the television 210.

Other methods for warning of imminent shutdown of power to the television 210 may be used. An audible warning tone may sound.

The standby power controller (SPC) 200 may include software allowing control of the warning mechanism. The brightness of the LED may be variable. It may be possible to set times when the warning should take certain forms. For example, an audible warning may be used at certain times of the day, whilst the LED is used at other times. At still further times, no warning at all may be given.

The standby power controller (SPC) 200 includes a power sensor 241 adapted to sense the power drawn through the Monitored and Controlled Outlets 204, 205, 206, 207. The power sensor 241 detects characteristics of the power flow through the outlet(s) 204, 205, 206, 207. When the characteristic is such as to indicate that all of the devices connected to Monitored and Controlled Outlets 204, 205, 206, 207 are in a standby mode, the power to the Monitored and Controlled Outlets 204, 205, 206, 207, and hence to the attached television 210 or AV equipment 212, is interrupted.

The standby power controller (SPC) 200 may include any number of Monitored and Controlled Outlets 204, 205, 206, 207, which may be monitored and controlled individually or together. The power sensor 241 may monitor the power drawn through all Monitored and Controlled Outlets 204, 205, 206, 207 in aggregate, or may monitor each Monitored and Controlled Outlet individually. Multiple power sensors 241 may be provided.

Devices other than a television 210 may be connected along with a television to the Monitored and Controlled Outlets 204, 205, 206, 207. In this case, the total load of all devices may be monitored for the characteristics indicating that all devices so connected are in a standby or unused state. This means that the power will only be withdrawn when all devices powered through the Monitored and Controlled Outlet(s) 204, 205, 206, 207 are determined to be in an unused state.

The power sensor 241 may use the falling of the power use below a threshold level as the power use characteristic indicating that the television 210 or other device is in standby mode. The threshold level may be fixed, or may be able to be modified either automatically or manually. Alternatively, the characteristic of the power flow may be small variations in the power level, indicating that the television 210 or other device is in use.

Uncontrolled Outlets 208, 209 are optionally provided to allow for power to be supplied to devices which should not have their power supply cut when the television 210 is not in use. Each of Uncontrolled Outlets 208, 209 supplies power at all times when the standby power controller (SPC) 200 is plugged in. Any number of Uncontrolled Outlets 208, 209 (including none) may be provided.

A third type of power outlet (not shown) may be provided. This non-monitored, controlled outlet is not monitored by the power sensor 241, so the power drawn by any load connected to the non-monitored, controlled outlet does not contribute to the determination that the monitored load is in a standby or unused state. When power is interrupted to the Uncontrolled Outlets 208, 209, power is also interrupted to this outlet.

The power sensor 241 senses power consumption through all or each of the Monitored and Controlled Outlets 204, 205, 206, 207. The sensed power is preferably true RMS power. The time at which this consumption occurs is added to the sensed power consumption to give appliance energy usage data.

The appliance energy usage data also includes details of when and under what circumstances power is supplied to the Monitored and Controlled Outlets 204, 205, 206, 207.

The appliance energy usage data may be for each individual outlet and hence for an individual appliance, where power sensing components capable of determining individual consumption are provided. Alternatively, the appliance energy usage data may be the aggregated usage for all or a subset of the Monitored and Controlled Outlets 204, 205, 206, 207.

The appliance energy usage data may be stored in an electronic memory provided in the standby power controller (SPC) 200, shown as base memory 242, for analysis or for later transmission to the sensor device 213, instead of (or as well as) being immediately sent to the sensor device 213.

The appliance energy usage data is transmitted to the sensor device 213 and is stored in an electronic memory, shown as sensor device memory 240. The sensor device memory 240 may be any suitable memory device, including, without limitation, addressable RAM and an accumulation register.

A portable communications device 226, shown as a smartphone, includes a transceiver compatible with the short range transceiver 223 in the sensor device 213. The smartphone 226 may be any smartphone used by any member of the household. The sensor device 213 and the smartphone 226 are Bluetooth paired to create a short range communications channel 225.

The smartphone 226 has access to mobile data link 235, which provides internet access. This provides a data channel to a remote monitoring entity, Utility 236. In other versions of the invention the data link 235 may be provided by a Wi-Fi link from the smartphone 226 to a household internet router. Any other convenient means to provide internet access may be used. In an alternative version of the invention, the data link 235 may be established by means which do not include the public internet.

The Utility 236 is preferably a utility which supplies electricity to the household. Alternatively, the Utility 236 may be a third party which provides advice on energy saving measures to the household. The third party may also provide a modified or unmodified version of the energy usage data of the household to the utility which provides electricity to the household.

The appliance energy usage data and the household energy usage data are transferred, via the short range communications channel 225, to the smartphone 226. The smartphone 226 runs software which is adapted to receive and store the household energy usage data and the appliance energy usage data from the sensor device 213.

The smartphone 226 will not always be within transmission range of the Bluetooth transceiver 223 in the sensor device 213. The transmission of the household energy usage data and the appliance energy usage data from the sensor device 213 to the smartphone 226 will happen opportunistically at some times when the sensor device 213 and the smartphone 226 are in transmission range of each other, and the short range communications channel 225 can be established. At these times, the appliance energy usage data stored by the sensor device 213 are transmitted to the smartphone 226. Software running on the smartphone 226 receives the appliance energy usage data. The data may be stored or further processed. The software running on the smartphone 226 uses internet access 235 in order to make contact with a remote monitoring entity, e.g., Utility 236.

The smartphone 226 transmits the appliance energy usage data, modified or unmodified, to the Utility 236. This may be done continuously or periodically while the smartphone 226 is in data communication with the sensor device 213 and internet. The smartphone 226 can receive data from the sensor device 213 only when the Bluetooth channel 225 is available.

The usage data allows the Utility 236 to study energy use of appliances. Such data from many households helps the Utility 236 to predict future demand. The data may also be used to predict the outcome of moves to reduce power consumption, or to encourage householders to move power consumption times to smooth peaks in demand.

The appliance energy usage data indicates to the Utility 236 that the standby power controller (SPC) 200 is installed, and the operational history of the SPC 200. This data can be used to calculate or estimate the amount of electrical energy which has been saved by the installation of the SPC 200. The installation of an SPC 200 may be paid for or subsidised by the Utility 236 in order to reduce energy usage. The actual or calculated figure for energy saving allows the Utility 236 to assess whether installation of the SPC 200 has been successful in saving energy. The Utility 236 may base the payment of the subsidy, either for this installation or for future installations, on this energy saving figure.

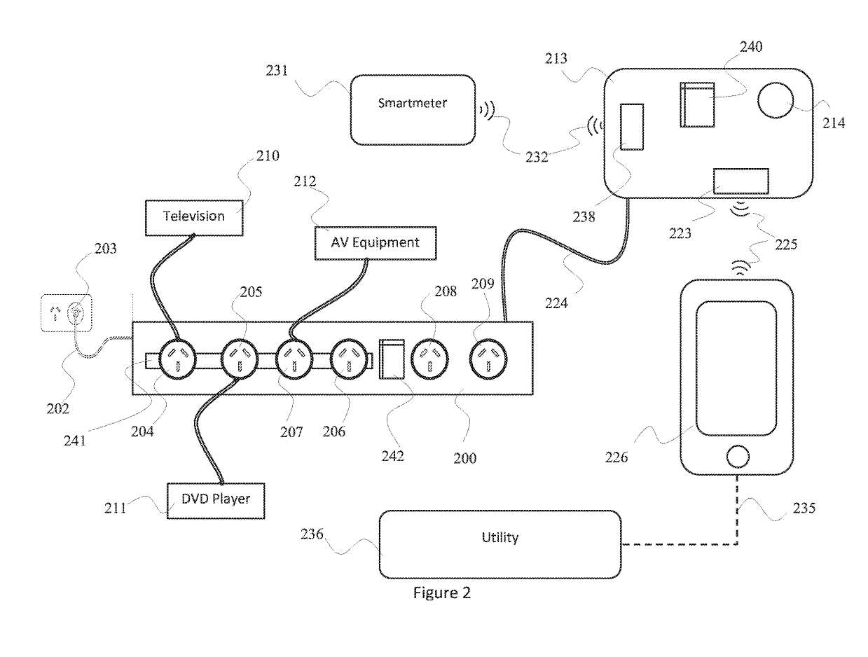

FIG. 2 depicts the standby power controller (SPC) 200 of FIG. 1, which operates as described in the description of FIG. 1, along with a Smartmeter 231 for metering the electricity consumption by the household.

The Smartmeter 231 is an electricity meter which meters of the flow of electricity into a premises (e.g., a residential household) for billing purposes. The Smartmeter 231 is able to measure the flow of electrical energy into the premises, and to record the household usage. The Smartmeter 231 includes a transceiver 251, e.g., a ZigBee transceiver.

The Smartmeter 231 transmits recorded household energy usage data via the external communications channel 250 to an energy utility which provides electricity to the premises (e.g., Utility 236), so that the data may be used for billing purposes. The communications channel 250 may be any suitable type of communication channel, including, without limitation, mobile data, Wi-Fi, and direct download to a physically present meter reader. Preferably, the communications channel 250 employs the ZigBee transceiver 251.

The external communications channel 250 generally has a low data throughput and a latency which is high, unpredictable, or both. There are a number of reasons for this. The Utility 236 will have a very large number of customers, and thus the chosen channel must be inexpensive to provide and operate. Where a chosen communications protocol allows a high data rate, such as mobile data networks, the access charges are often significant. Accordingly, data transmissions are kept to a minimum, using short bursts at long intervals, perhaps communicating once per day or less. This results in very high latency and low effective data rates, such that data is not received by the Utility 236 in real time or near real time, and the amount of data received is relatively small.

In the illustrated embodiment, the external communication channel 250 employs the ZigBee transceiver and a mesh network. ZigBee is a relatively low power protocol, with relatively short range, but where many devices are installed over a wide area, a mesh network can be set up. Since the Utility 236 controls all of the devices in the network, access costs are minimal, but the possible data rate for any individual Smartmeter 231 in the mesh is low, if all the Smartmeters in the mesh are to communicate with the Utility 236. Further, the exact data path from a given Smartmeter 231 to the Utility 236 is not predictable, hence the latency is unpredictable, but may be on the order of hours or days. This results in very high latency and low effective data rates, such that data is not received by the Utility 236 in real time or near real time, and the amount of data received is relatively small.

The latency and data rate issues are not of concern for billing data. Customers are rarely billed more often than monthly, and may be billed quarterly. Billing data is interval data, and as such typically consists at most of a single result every half or quarter hour. It may consist only of a single, accumulated result for the entire billing period. The quantity of data is small, and the range of acceptable delivery time is broad. Low data rate, high latency communication channels as described are acceptable for this traffic.

The sensor device 213 includes a meter data transceiver 238, preferably a ZigBee transceiver, though any other appropriate communications protocol may be used. The sensor device 213 is in data communication with the Smartmeter 231 via internal communications channel 232. Preferably, this internal communications channel 232 uses ZigBee, employing the ZigBee transceiver 251 in the Smartmeter 231 and the ZigBee transceiver 238 in the sensor device 213. Any other suitable communications protocol may be employed instead of, or in addition to, the ZigBee protocol.

The Smartmeter 231 communicates with the sensor device 213 via wireless link 232, which uses meter data transceiver 238. The Smartmeter 231 transfers the household energy usage data to the sensor device 213. The household energy usage data is stored in sensor device memory 240.

The capacity of communications channel 232 is not constrained in the way that the capacity of the external communications channel 250 is constrained. The Smartmeter 231 is adapted to provide household energy usage data at a greater data rate on the internal communications channel 232. Compared to the external communications channel 250, the internal communications channel 232 is a high data rate, low latency channel. Accordingly, real time, continuous power use data may be provided from the Smartmeter 231 to the sensor device 213. Data may be provided at intervals ranging from a few milliseconds to tens or hundreds of seconds. Preferably, the Smartmeter 231 is adapted to provide data at approximately seven second intervals.

This fine-grained household energy usage data, made available on the internal communications channel 232, is of value to third parties. Where the premises is a domestic household, these third parties may include current or potential providers of services to the household, which may also include the Utility 236 providing electricity to the household.

The fine-grained household energy usage data may be analysed by a third party to determine what appliances are being used within the household, and at what times the appliances are being used. This household energy usage data may be used to provide recommendations to the household about replacement of appliances with appliances having greater energy efficiency, and/or about changing usage patterns of appliances to save energy, or to reduce peak energy usage. The household energy usage data may be used by a Utility 236, when combined with data from other households to which the Utility 236 provides electricity, to estimate future electricity demand which will be placed on the Utility 236.

Access to the data by third parties external to the household requires a receiver within the premises and a means to communicate the received data to the third party. The appliance energy usage data, collected as described in the description of FIG. 1, and the household energy usage data are transferred via the short range communications channel 225 to the smartphone 226. The smartphone 226 runs software which is adapted to receive the household energy usage data and the appliance energy usage data from the sensor device 213, and to store that data.

The smartphone 226 will not always be within transmission range of the Bluetooth transceiver 223 in the sensor device 213. The transmission of the household energy usage data and the appliance energy usage data from the sensor device 213 to the smartphone 226 will happen opportunistically at some times when the sensor device 213 and the smartphone 226 are in transmission range of each other, and the short range communications channel 225 can be established. At these times, the appliance energy usage data and the household energy usage data stored by the sensor device 213 are transmitted to the smartphone 226.

Software running on the smartphone 226 receives the combined household energy usage data and appliance energy usage. This usage data may be stored or further processed.

The software running on the smartphone 226 uses internet access 235 in order to make contact with Utility 236. The smartphone transmits the usage data, modified or unmodified, to a remote monitoring entity, which may be Utility 236. This may be done continuously while the smartphone is in data communication with the sensor device 213 and internet 235, or periodically. The smartphone 226 can receive data from the sensor device 213 only when the Bluetooth channel 225 is available.

The household energy usage data allows the Utility 236 to study energy use of appliances. Such data from many households helps the Utility 236 to predict future demand. The data may also be used to predict the outcome of moves to reduce power consumption or to encourage householders to move power consumption times to smooth peaks in demand.

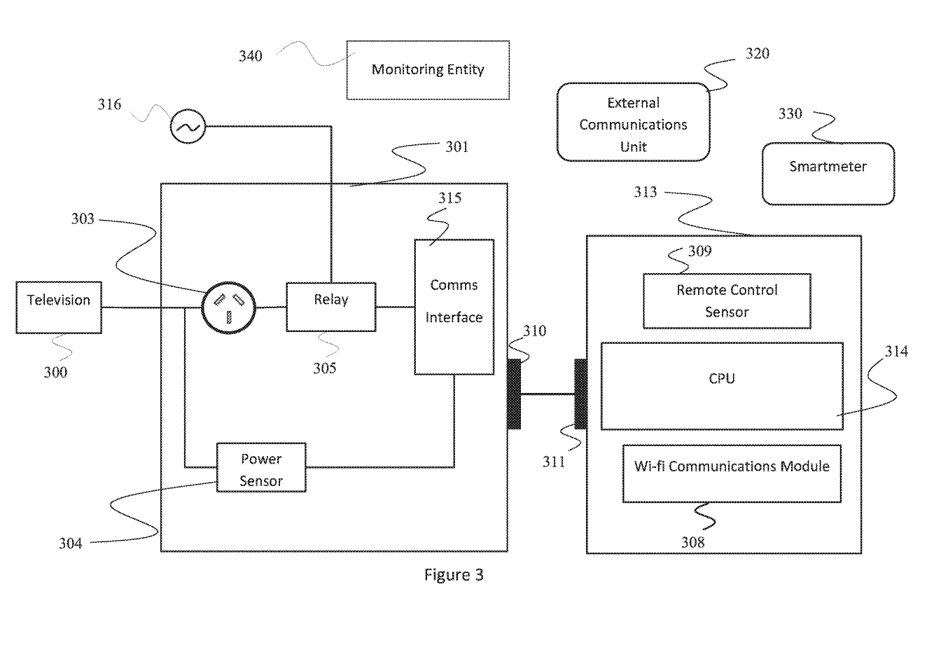

FIG. 3 shows a block diagram representation of a standby power controller (SPC) incorporating the invention. An SPC 301 supplies power to a television 300, and optionally to other audiovisual equipment. A Sensor Unit 313, which houses sensors and a CPU 314, provides all the calculation and analytical functionality of the SPC 301.

The Sensor Unit 313 includes plug connector 311, whereas the standby power controller (SPC) 301 includes plug connector 310. In the illustrated embodiment, these connectors are USB connectors. The SPC 301 and the Sensor Unit 313 are connected by a USB link between these connectors 310 and 311. Any plug-connected wired communications protocol may be used. An advantage of a wired connection is that power can be easily supplied from the SPC 301 to the Sensor Unit 313 over such a connection. In this case the Sensor Unit 313 does not need a battery or other independent power supply. Alternatively or additionally, the Sensor Unit 313 may have an independent power supply, and the data connection may be provided by a wireless protocol.

The standby power controller (SPC) 301 includes a connection to external electricity supply 316. Electricity is provided via relay 305 to one or more Monitored and Controlled Outlets 303 (only one being shown). The power drawn through Monitored and Controlled Outlet 303 is monitored by power sensor 304. Electricity is provided to television 300 by Monitored and Controlled Outlet 303. Communications Interface 315 provides data communication with CPU 314 located in the Sensor Unit 313.

The Sensor Unit 313 includes external communications circuitry, here provided by Wi-Fi Communications Module 308. The Wi-Fi Communications Module 308 provides data communication for CPU 314 to an External Communications Unit 320, here provided by a broadband router. In general, this will be the router which provides internet access for the household. The Wi-Fi Communications Module 308 communicates with the router 320 via the household Wi-Fi network. In other versions of the invention, the External Communications Unit 320 may be a smartphone or smartphones used by members of the household. In this case, the External Communications Unit 320 will, in general, be available only intermittently, that is, when the user of the smartphone is present in the household.

The Sensor Unit 313 includes Remote Control Sensor 309. The Remote Control Sensor 309 senses activity of any appliance remote control unit, and is preferably provided as an infra-red (IR) detector, which is able to detect usage of IR based remote controls. The Remote Control Sensor 309 may be configured to detect additional or other remote control communications, including (for example) RF4CE communications, which are used to control many cable television units.

In use, the Remote Control Sensor 309 provides data to the CPU 314 concerning use of an IR remote control to control the television 300. The power sensor 304 provides data about the power state of the television 300 to the CPU 314. As discussed with respect to FIG. 1, the CPU 314 uses this data to determine when the television 300 has entered a low power standby mode, or is in Active Standby (that is, on but not being actively watched by a user). In either case, the CPU 314 controls relay 305 to remove the electricity supply from the television 300, saving energy. When the Remote Control Sensor 309 detects IR indicating that the television 300 is to be turned on, CPU 314 controls the relay 305 to return electricity supply to the television 300.

The Wi-Fi Communications Module 308 allows data collected by the CPU 314 to be communicated to an external monitoring entity 340 via the External Communications Unit 320. The operation of the standby power controller (SPC) 301, including calculations of energy saved may be communicated to the monitoring entity 340. In some versions of the invention where the External Communications Unit 320 is a smartphone which is available only intermittently, the external monitoring entity 340 may receive only data which is being collected at times when the smartphone is present in the household. In other versions of the invention, the Sensor Unit 313 may include electronic memory able to store data which is to be transmitted to the external monitoring entity 340 during periods when the smartphone is unavailable because it is absent from the household or otherwise not within communication range of the Wi-Fi Communications Module 308. When the smartphone again comes into communication range, the stored data is communicated to the smartphone for transmission to the external monitoring entity 340.

A Smartmeter or other device 330 for monitoring the overall electricity use of the household, or a part of the household which includes the standby power controller (SPC) 301 installation, is also provided. In other versions of the invention, the device 330 may have a purely measuring and communication function, independent of the metering of the electricity supply. As examples, the device 330 might instead be provided by current clamp meters which use sensors which encircle the household electricity supply conductors, and DIN rail meters.

The standby power controller (SPC) 301 may communicate the calculated or estimated energy savings to the monitoring entity 340. The SPC 301 may use the raw data from the power sensor 304 and the Remote Control Sensor 309, along with the timing of the relay 305 control activity, to calculate or estimate energy savings occasioned by the installation of the SPC 301. The SPC 301 communicates the raw data from the power sensor 304 and the Remote Control Sensor 309, along with the timing of the relay 305 control activity, to the monitoring entity 340 via the External Communications Unit 320. The monitoring entity 340 may use the raw data to calculate or estimate energy savings occasioned by the installation of the SPC 301.

The external monitoring entity 340 may be any entity having an interest in the energy use of the household and/or appliances within the household. Without limitation, this may be an energy supply utility, a demand aggregator, an entity offering energy optimisation services, or an energy distribution utility.

The monitoring entity 340 may wish to engage in disaggregation of the energy usage of the household. In this case, the monitoring entity 340 receives the data indicating the total energy usage of the household, or part of the household. This aggregate usage data shows the energy usage of all of the electrical devices using energy in the household at a given time. When disaggregating energy usage, the monitoring entity 340 wishes to separate out the energy usage which may be attributed to each individual appliance. This allows the energy usage of the household to be analysed and suggestions made to reduce total or peak energy usage. For example, if it could be determined that a pool pump and an air conditioner were routinely being run together, but that the air conditioner was not run at night, it would be possible to recommend that the pool pump usage be moved to the night time in order to reduce the peak usage. When enacted over a large number of households, such changes will allow an energy utility to reduce the peak energy which it must supply, even when the total amount of energy supplied is not varied.

The external monitoring entity 340 may be any entity having an interest in the energy use of the household and/or appliances within the household. Without limitation, this may be an energy supply utility, a demand aggregator, an entity offering energy optimisation services or an energy distribution utility.

A major cause of failure by standby power controllers (SPCs) to save power is de-installation when a user finds the action of the SPC intrusive or annoying and simply removes the SPC, preventing any energy saving. False detection of Active Standby, and subsequent cutting of power to an in-use television 300, is a major cause of this failure.

The standby power controller (SPC) 301 may also report the frequency of use of the television remote control to the monitoring entity 340. The user monitoring entity 340 may also collect information on how often and at what times the user uses the remote control to prevent the SPC 301 removing power from the television 300 after a warning has been given. These are occasions when the SPC 301 has determined incorrectly that the television 300 is in Active Standby when a user is still actively watching the television 300. This information may be used to determine a more accurate pattern which indicates that the television 300 is in fact in Active Standby, allowing less occasions where the SPC 301 attempts to or does cut power to a television 300 in active use. Improvements in the determination of Active Standby reduce de-installation.

The monitoring entity 340 may determine from remote control usage information when correct and incorrect determinations of Active Standby are made. Where this information shows that incorrect determinations are rare, user satisfaction with the standby power controller (SPC) 301 is likely to be improved, leading to lower de-installation rates.

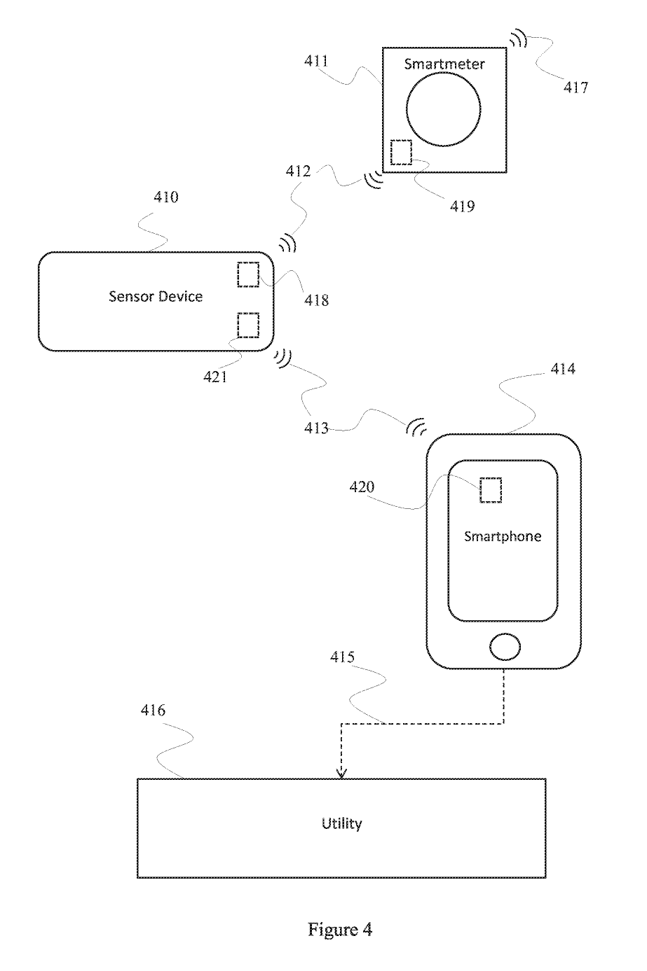

FIG. 4 shows a sensor device 410 which includes a data processor and data storage (neither being shown), as well as a transceiver 418 (e.g., a ZigBee transceiver) and a transceiver 421 (e.g., a Bluetooth transceiver). In other versions of the invention, these transceivers may be, without limitation, z-wave or Wi-Fi transceivers, or transceivers implementing any other suitable communications protocol.

The sensor device 410 may include sensors to detect any environmental characteristics of the premises in which it is installed. In particular, the sensor device 410 may sense environmental characteristics associated with energy use by the premises. These may include, without limitation, temperature, humidity, electrical appliance use, occupancy and lighting levels.

An electricity meter 411, that is, a Smartmeter or other device which provides metering of the flow of electricity into a premises such as a residential household for billing purposes, is also provided. The Smartmeter 411 is able to measure the flow of electrical energy into the premises, and to record the household usage. The Smartmeter 411 includes a ZigBee transceiver 419.

The Smartmeter 411 transmits recorded household energy usage data via external communications channel 417 to an energy utility 416 which provides electricity to the premises for billing purposes. The external communications channel 417 may be any suitable type of communication channel, including, without limitation, mobile data, Wi-Fi, and direct download to a physically present meter reader. Preferably, the external communications channel 417 employs the ZigBee transceiver 419 and a mesh network.

The sensor device 410 is in data communication with the Smartmeter 411 via internal communications channel 412. This internal communications channel 412 preferably uses ZigBee, employing the ZigBee transceiver 419 in the Smartmeter 411 and the ZigBee transceiver 418 in the sensor device. Any other suitable communications protocol may be employed.

The capacity of the internal communications channel 412 is not constrained in the way that capacity on external communications channel 417 is constrained. The Smartmeter 422 is adapted to provide household energy usage data at a greater data rate on the internal communications channel 412. Accordingly, real-time continuous power use data may be provided from the Smartmeter 411 to the sensor device 410. Data may be provided at intervals ranging from a few milliseconds to tens or hundreds of seconds. Preferably, the Smartmeter 411 is adapted to provide data at approximately seven second intervals.

A smartphone 414 includes a short range transceiver 420, preferably a Bluetooth transceiver. In combination with the Bluetooth transceiver 421 provided by the sensor device, this transceiver 420 is used to implement a short range communications channel 413.

The smartphone 414 has the capacity to transmit data to a receiving entity 416 remote from the household. In a preferred embodiment, this is a mobile data link 415, providing internet access. In other versions of the invention the data link 415 may be provided by a Wi-Fi link from the smartphone to a household internet router. Any other convenient means to provide the data link 415 may be used.

Preferably, the receiving entity 416 is a utility which supplies electricity to the household. The receiving entity 416 could be a third party which provides advice on energy saving measures to the household. The third party may also provide a modified or unmodified version of the household energy usage data to the utility which provides electricity to the household.

In use, the sensor device 410 establishes a link to the Smartmeter 411. Household energy usage data is received from the Smartmeter 411 by the sensor device 410 via the internal communications link 412. The sensor device 410 stores the household energy usage data.

The smartphone 414 may be any smartphone used by a member of the household. The sensor device 410 and the smartphone 414 are Bluetooth paired to create short range communications channel 413. The smartphone 414 runs software which is adapted to receive the household energy usage data from the sensor device 410 and to store that data.

The smartphone 414 will not always be within transmission range of the Bluetooth transceiver 421 in the sensor device 410. The transmission of the household energy usage data from the sensor device 410 to the smartphone 414 will happen opportunistically at some times when the sensor device transceiver 421 and the smartphone transceiver 420 are within transmission range of each other, at which time the short range communications channel 413 can be established. At these times, the household energy usage data stored by the sensor device 410 is transmitted to the smartphone 414.

Software running on the smartphone 414 receives the household energy usage data. The household energy usage data may be stored or further processed. The smartphone 414 includes an internet access facility 415. The internet access facility 415 may be provided by a mobile data network, or by the smartphone 414 having access to the household internet connection.

The software running on the smartphone uses internet access 415 in order to make contact with external party 416. The external party 416 may be a service provider providing energy efficiency services to the household. The external party 416 may be the utility supplying electricity to the household.

The smartphone 414 transmits the usage data, modified or unmodified, to the external party 416. This may be done continuously while the smartphone 414 is in data communication with the sensor device 410 and internet 415, or periodically. The smartphone 414 can receive data from the sensor device 410 only when the Bluetooth channel 413 is available. This channel is in general available intermittently as the smartphone 414 accompanies its user around and away from the household.

Where reference has been made to infra-red remote controls and corresponding infra-red sensors, it will be understood that any form of remote control and corresponding sensors may be employed, including (for example) radio frequency remote controls.

Similarly, where reference has been made to Bluetooth, Wi-Fi, and other wireless protocols as the communication mode between devices or parties, any suitable wired or wireless communications protocols may be used.

The invention is not intended to be limited to the exemplary versions of the invention described above, but rather is intended to be limited only by the claims set out below. Thus, the invention encompasses all different versions that fall literally or equivalently within the scope of these claims.

What is claimed is:

1. A method for communicating energy usage data to a remote monitoring entity including the steps of:
a. providing a sensor device which receives energy usage data from a standby power controller,
b. receiving the energy usage data at a remote monitoring entity, the energy usage data being communicated from the sensor device through a communications device.

2. The method of claim 1 wherein the sensor device includes a first transceiver which communicates the energy usage data to the communications device via one or more of:
a. the Wi-Fi protocol, and
b. the Bluetooth protocol.

3. The method of claim 2 wherein the energy usage data includes appliance energy usage data representing energy drawn through the standby power controller.

4. The method of claim 3 wherein the standby power controller includes:
a. a power sensor adapted to measure energy drawn through the standby power controller and provide the appliance energy usage data therefrom;
b. a processor adapted to determine from the measured energy whether one or more devices connected to the standby power controller are in a standby state; and
c. a switch adapted to remove power from an appliance connected to the standby power controller when the appliance is determined to be in the standby state.

5. The method of claim 4:
a. wherein the sensor device further includes a meter data transceiver adapted to receive household energy usage data from an electricity meter;
b. wherein the first transceiver communicates the household energy usage data to the communications device as part of the energy usage data.

6. The method of claim 5 wherein the electricity meter is a Smartmeter.

7. The method of claim 5 wherein the meter data transceiver employs the ZigBee protocol.

8. The method of claim 2 wherein the energy usage data includes household energy usage data from an electricity meter.

9. The method of claim 8 wherein the sensor device includes a meter data transceiver which receives the household energy usage data from the electricity meter.

10. The method of claim 1 wherein the energy usage data includes:
a. appliance energy usage data representing energy drawn through the standby power controller, and
b. household energy usage data from an electricity meter.

11. The method of claim 1 wherein the energy usage data is intermittently communicated from the sensor device to the communications device.

12. The method of claim 1 wherein the communications device is one or more of a smartphone, a tablet computer and a notebook computer.

13. A sensor device including:
a. a power sensor adapted to measure power drawn through a standby power controller and provide appliance energy usage data representing the measured power;
b. a processor adapted to determine from the measured power that one or more devices connected to the standby power controller are in a standby state;
c. a switch adapted to remove power from a television connected to the standby power controller when the television is determined to be in the standby state;
d. a first transceiver adapted to communicate the appliance energy usage data to a communications device, wherein the communications device is adapted to communicate the appliance energy usage data to a remote monitoring entity.

14. The sensor device of claim 13:
a. further including a meter data transceiver adapted to receive household energy usage data from an electricity meter;
b. wherein:
(1) the first transceiver is further adapted to communicate the household energy usage data to the communications device, and
(2) the communications device is adapted to communicate the appliance energy usage data to a remote monitoring entity.

15. The sensor device of claim 14 wherein the electricity meter is a Smartmeter.

16. The sensor device of claim 14 wherein the meter data transceiver employs the ZigBee protocol.

17. The sensor device of claim 14 wherein the first transceiver is a Wi-Fi transceiver.

18. The sensor device of claim 13 wherein the first transceiver employs the Bluetooth protocol.

19. The sensor device of claim 13 wherein the first transceiver is a Wi-Fi transceiver.

20. The sensor device of claim 13 wherein the sensor device and the standby power controller are integrated within a single housing.

21. The sensor device of claim 13 wherein the communication device is one or more of a smartphone, a tablet computer, and a notebook computer.

22. A sensor device including:
a. a meter data transceiver adapted to receive household energy usage data from an electricity meter;
b. a first transceiver adapted to transmit the household energy usage data to a communications device, the communications device communicating the household energy usage data to a remote monitoring entity.

23. The sensor device of claim 22 wherein the communications device is one or more of a smartphone, a tablet computer and a notebook computer.

24. The sensor device of claim 22 wherein the meter data transceiver uses the ZigBee protocol.

25. The sensor device of claim 22 wherein the first transceiver is a Bluetooth transceiver.

26. The sensor device of claim 22 further including an electronic memory adapted to store the household energy usage data, wherein the electronic memory receives the household energy usage data from the meter data transceiver and provides the household energy usage data to the first transceiver.
